(19) United States
(12) Patent Application Publication
(10) Pub. No.: US 2015/0009636 A1
(43) Pub. Date: Jan. 8, 2015

(54) FLEXIBLE DISPLAY DEVICE AND METHOD FOR CONTROLLING SAME

(71) Applicant: Samsung Display Co., LTD., Yongin-City (KR)

(72) Inventors: Chang-Yong JEONG, Yongin-si (KR); Jae-Hyun PARK, Suwon-si (KR)

(21) Appl. No.: 14/321,295

(22) Filed: Jul. 1, 2014

(30) Foreign Application Priority Data
Jul. 3, 2013 (KR) 10-2013-0077583

(51) Int. Cl. H05K 1/02; B65H 75/44; H05K 5/00

(52) U.S. Cl. CPC H05K 1/028; H05K 5/0017; B65H 75/4484
USPC 361/749; 242/390

(57) ABSTRACT

A flexible display device includes a flexible display panel, a first roller configured to wind the flexible display panel thereon, and a roller controller configured to rotate the first roller in a first direction and in a second direction opposite to the first direction, and to select from between the first direction and the second direction, such that the flexible display panel is wound selectively thereon in either of the first direction and the second direction.

### CROSS-REFERENCE TO RELATED APPLICATION(S)

This application claims priority under 35 USC §119 to Korean Patent Applications No. 10-2013-0077583, filed on Jul. 3, 2013 in the Korean Intellectual Property Office (KIPO), the contents of which are incorporated herein in their entirety by reference.

### BACKGROUND

1. Technical Field

Example embodiments relate generally to a display device. More particularly, embodiments of the inventive concept relate to a flexible display device and a method for controlling the flexible display device.

2. Description of the Related Art

Recently, efforts have been made to develop flexible displays that can be bent or folded, in an attempt to reduce the size of electronic devices. A flexible display can be used in various electronic devices such as a television, a laptop computer, a mobile phone, a smart phone, an electronic book, a navigation system, a game console, etc.

Conventional electronic devices having a flexible display panel can be wound in one direction. If the flexible display panel is wound up too many times, the flexible display panel may eventually be damaged to the point that it cannot maintain its flatness when the flexible display panel is unwound.

### SUMMARY

Some example embodiments provide a flexible display device capable of preventing a deterioration of a flexible display panel that is caused by being wound in one direction for an excessive amount of time.

Some example embodiments provide a method of controlling a flexible display device capable of maintaining performance and status of the flexible display device, and extending the life span of the flexible display device.

According to some example embodiments, a flexible display device includes a flexible display panel, a first roller configured to wind the flexible display panel thereon, and a roller controller configured to rotate the first roller in a first direction and in a second direction opposite to the first direction, and to select from between the first direction and the second direction, such that the flexible display panel is wound selectively thereon in either of the first direction and the second direction.

In example embodiments, the roller controller may be configured to rotate the first roller in the first direction when the flexible display panel was previously wound in the second direction, and may be configured to rotate the first roller in the second direction when the flexible display panel was previously wound in the first direction.

In example embodiments, the roller controller may be configured to record a first number of times that the flexible display panel is wound in the first direction and a second number of times that the flexible display panel is wound in the second direction, and may be configured to select from among the first and second directions so as to rotate the first roller such that the flexible display panel is wound in a direction corresponding to a smaller one of the first number of times or the second number of times.

In example embodiments, the roller controller may be configured to record a first duration during which the flexible display panel is wound in the first direction and a second duration during which the flexible display panel is wound in the second direction, and may be configured to select from among the first and second directions so as to rotate the first roller such that the flexible display panel is wound in a direction corresponding to a shorter one of the first duration and the second duration.

In example embodiments, if a duration during which the flexible display panel is wound in one of the first and second directions exceeds a predetermined time, the roller controller may be configured to rotate the first roller such that the flexible display panel is wound in the other one of the first and second directions.

In example embodiments, the roller controller may be configured to periodically rotate the first roller such that the flexible display panel is successively wound in alternating ones of the first direction and the second direction.

In example embodiments, a curvature of the flexible display panel when the flexible display panel is wound in the first direction may be different from a curvature of the flexible display panel when the flexible display panel is wound in the second direction.

In example embodiments, the flexible display device may further include a second roller disposed opposite to the first roller relative to the flexible display panel, the second roller configured to wind the flexible display panel.

In example embodiments, the roller controller may be configured to rotate the first roller and the second roller in a same direction.

In example embodiments, the roller controller may be configured to rotate the first roller and the second roller in opposite directions.

In example embodiments, a curvature of the flexible display panel wound by the first roller may be different from a curvature of the flexible display panel wound by the second roller.

According to some example embodiments, a method of controlling a flexible display device includes receiving a request to wind a flexible display panel, determining a direction in which the flexible display panel is to be wound, the direction determined from among a first direction and a second direction opposite to the first direction, rotating at least one roller to wind the flexible display panel in the determined one of the first direction and the second direction, and storing a winding record including information corresponding to the determined one of the first direction and the second direction.

In example embodiments, the determining may further include selecting a direction opposite to a previous direction in which the flexible display panel was wound.

In example embodiments, the storing may further include storing a first number of times that the flexible display panel is wound in the first direction and a second number of times that the flexible display panel is wound in the second direction.

In example embodiments, the determining may further include comparing the first number of times to the second number of times, and selecting the direction in which the flexible display panel is to be wound as the direction corresponding to a smaller one of the first number of times and the second number of times.

In example embodiments, the storing may further include storing a first duration during which the flexible display panel is wound in the first direction and a second duration during which the flexible display panel is wound in the second direction.

In example embodiments, the determining may further include comparing the first duration to the second duration, and selecting the direction in which the flexible display panel is to be wound as the direction corresponding to a smaller one of the first duration or the second duration.

In example embodiments, the receiving may further comprise conditionally receiving the request when a duration during which the flexible display panel is wound in one of the first and second directions exceeds a predetermined time, and the determining may further include selecting a direction opposite to the one of the first and second directions.

In example embodiments, the receiving may further comprise receiving ones of the requests periodically, and the determining may further include selecting a direction in which the flexible display panel is to be wound as the direction opposite to a direction in which the flexible display panel was immediately previously wound.

Therefore, a flexible display device according to example embodiments may prevent a deterioration of a flexible display panel that is caused by being wound only in one direction.

In addition, a flexible display device and a method for controlling the flexible display device according to example embodiments may maintain a performance for a longer time, and may extend the life span of the flexible display panel.

### BRIEF DESCRIPTION OF THE DRAWINGS

Illustrative, non-limiting example embodiments will be more clearly understood from the following detailed description taken in conjunction with the accompanying drawings.

FIG. 1A is a plan view illustrating a flexible display device according to example embodiments, and FIG. 1B is a perspective view illustrating a flexible display device of FIG. 1A.

FIGS. 2A and 2B are diagrams illustrating an example in which a flexible display panel included in a flexible display device of FIG. 1A is wound.

FIG. 3 is a diagram illustrating an example in which a flexible display device of FIG. 1A is controlled such that a flexible display panel is selectively wound in a first direction or a second direction.

FIG. 4 is a diagram illustrating another example in which a flexible display device of FIG. 1A is controlled such that a flexible display panel is selectively wound in a first direction or a second direction.

FIGS. 5A and 5B are diagrams illustrating still another example in which a flexible display device of FIG. 1A is controlled such that a flexible display panel is selectively wound in a first direction or a second direction.

FIG. 6A is a plan view illustrating a flexible display device according to example embodiments, and FIG. 6B is a perspective view illustrating a flexible display device of FIG. 6A.

FIGS. 7A and 7B are diagrams illustrating an example in which a flexible display panel included in a flexible display device of FIG. 6A is wound.

FIG. 8 is a diagram illustrating an example in which a flexible display device of FIGS. 7A and 7B is controlled.

FIGS. 9A and 9B are diagrams illustrating another example in which a flexible display panel included in a flexible display device of FIG. 6A is wound.

FIG. 10 is a diagram illustrating an example in which a flexible display device of FIGS. 9A and 9B is controlled.

FIGS. 11A and 11B are diagrams illustrating examples of curvature of a flexible display panel when it is wound.

FIG. 12 is a flow chart illustrating a method for controlling a flexible display device according to example embodiments.

### DETAILED DESCRIPTION OF THE EMBODIMENTS

Various example embodiments will be described more fully hereinafter with reference to the accompanying drawings, in which some example embodiments are shown.

The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. The drawings are not to scale. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

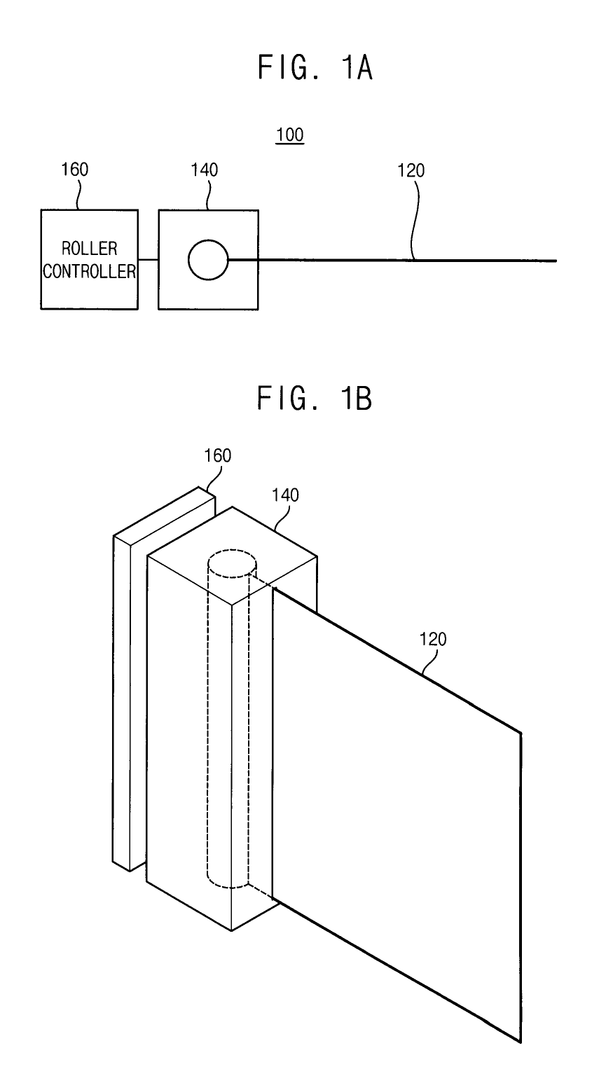

FIG. 1A is a plan view illustrating a flexible display device according to example embodiments, and FIG. 1B is a perspective view illustrating a flexible display device of FIG. 1A.

Referring to FIGS. 1A and 1B, a flexible display device 100 may include a flexible display panel 120, a first roller 140, and a roller controller 160.

The flexible display panel 120 is flexible and not rigid, and thus may be bent or folded. The first roller 140 may be rotated to wind the flexible display panel 120 in a first direction (for example, clockwise) or in a second direction (for example, counter clockwise). The first roller 140 may employ various structures or mechanisms to wind the flexible display panel 120. For example, the first roller 140 may comprise a roller body and a housing. The roller body may be rotated to wind the flexible display panel 120 in the first direction or in the second direction such that the flexible display panel 120 may be wound up or rolled up, and kept in the housing.

The roller controller 160 may rotate the first roller 140 selectively in the first direction or in the second direction for maintaining a performance of the flexible display panel 120. For example, if the flexible display device 100 receives a request to wind the flexible display panel 120 from a user, or receives a request to wind the flexible display panel 120 where a duration for which the flexible display panel 120 has previously been wound in a certain direction exceeds a predetermined time, in response to the request, the roller controller 160 may rotate the first roller 140 selectively in the first direction or in the second direction.

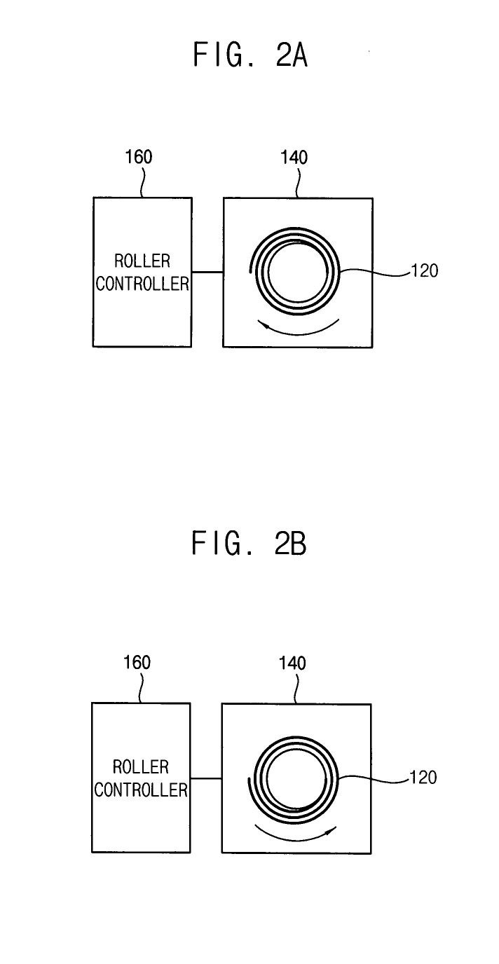

FIGS. 2A and 2B are diagrams illustrating an example in which a flexible display panel is wound.

Referring to FIGS. 2A and 2B, a flexible display panel 120 may be wound for minimizing size. A roller controller 160 may rotate a first roller 140 selectively in a first direction or in a second direction opposite to the first direction, so as to wind the flexible display panel 120. As illustrated in FIG. 2A, the roller controller 160 may rotate the first roller 140 in the first direction. As illustrated in FIG. 2B, the roller controller 160 may rotate the first roller 140 in the second direction (i.e. in the direction of the arrow shown). The roller controller 160 may rotate the first roller 140 selectively in the first direction or in the second direction, such that the flexible display panel 120 can be wound in either direction. Therefore, the flexible display device 100 may prevent a deterioration of a flexible display panel 120 that is caused by being wound only in one direction. The flexible display device 100 may thus maintain its performance for a longer time, resulting in extended life span. In one example embodiment, the roller controller 160 may rotate the first roller 140 in the first direction when the flexible display panel 120 was last wound in the second direction, and may rotate the first roller 140 in the second direction when the flexible display panel 120 was last wound in the first direction. In another example embodiment, the roller controller 160 may store or record a first number of times that the flexible display panel 120 is wound in the first direction and a second number of times that the flexible display panel 120 is wound in the second direction, and may rotate the first roller 140 such that the flexible display panel 120 is wound in a direction corresponding to a smaller one of the first number of times or the second number of times. In another example embodiment, the roller controller 160 may store a first duration during which the flexible display panel 120 is wound up in the first direction and a second duration during which the flexible display panel 120 is wound up in the second direction, and may rotate the first roller 140 such that the flexible display panel 120 is wound in a direction corresponding to a shorter one of the first duration or the second duration.

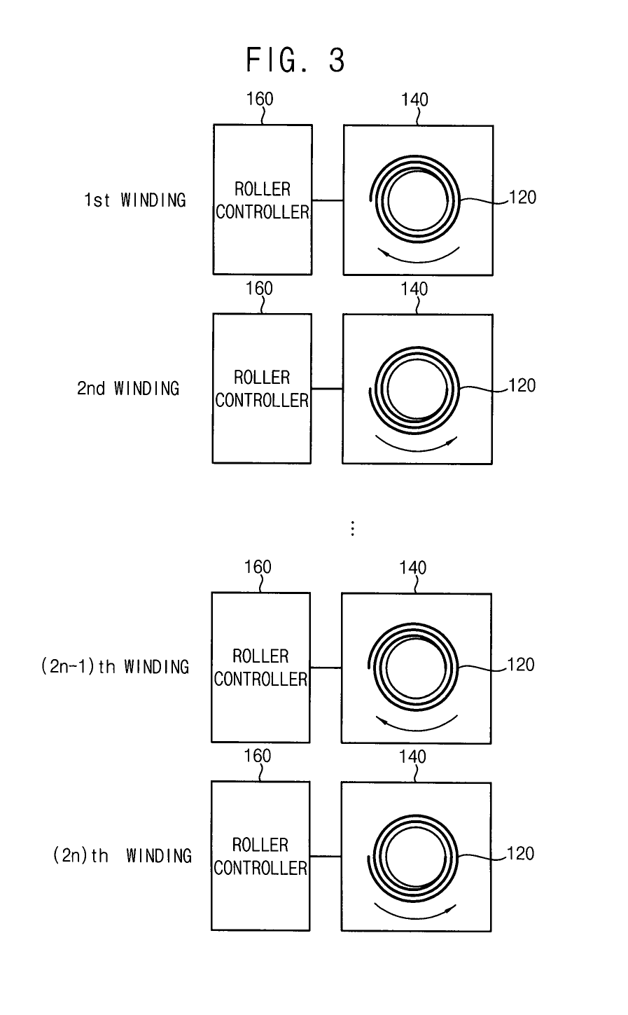

FIG. 3 is a diagram illustrating an example in which a flexible display device of FIG. 1A is controlled such that a flexible display panel is selectively wound in a first direction or a second direction.

Referring to FIG. 3, a roller controller 160 may rotate a first roller 140 in a direction opposite to the direction in which a flexible display panel 120 was last wound. In other words, the roller controller 160 may rotate the first roller 140 in a first direction when the flexible display panel 120 was last wound in a second direction, and rotate the first roller 140 in the second direction when the flexible display panel 120 was last wound in the first direction. For example, the roller controller 160 may initially rotate the first roller 140 in the first direction for winding the flexible display panel 120. Thereafter, the roller controller 160 may rotate the first roller 140 in the second direction opposite to the first direction for unwinding the flexible display panel 120. When the flexible display device 100 is to roll up the panel 120 a second time, the roller controller 160 may rotate the first roller 140 in the second direction for winding the flexible display panel 120. Likewise, when the panel 120 is to be rolled up for the ‘2n−1’th time (i.e. an odd number of times), the roller controller 160 may rotate the first roller 140 in the first direction. And when the panel 120 is to be rolled up for the ‘2n’th time (i.e. an even number of times), the roller controller 160 may rotate the first roller 140 in the second direction.

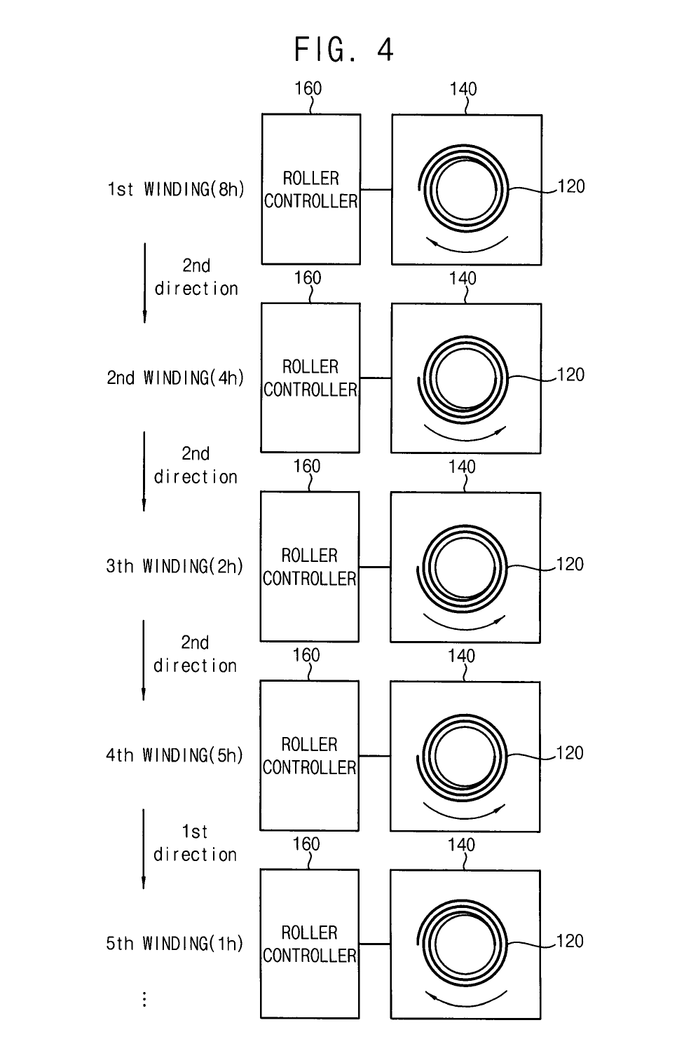

FIG. 4 is a diagram illustrating another example in which a flexible display device of FIG. 1A is controlled such that a flexible display panel is selectively wound in a first direction or a second direction.

Referring to FIG. 4, a roller controller 160 may store a first duration which is the total amount of time during which a flexible display panel 120 has been wound in a first direction, as well as a second duration corresponding to the total amount of time during which the flexible display panel 120 has been wound in a second direction, and may rotate a first roller 140 such that the flexible display panel 120 is wound in a direction corresponding to a shorter one of the first duration or the second duration. For example, when a flexible display panel 120 is to be rolled up for the first time (such as when the flexible display device 100 is to remain unused for some period of time), the roller controller 160 may rotate the first roller 140 in the first direction for winding the flexible display panel 120, and the flexible display panel 120 may remain wound, for example, for about 8 hours. When the flexible display panel 120 is to be rolled up for the second time, the roller controller 160 may rotate the first roller 140 in the second direction corresponding to a shorter one of the first duration (8 hours) or the second duration (0 hours), and the flexible display panel 120 may remain rolled up, for example, for about 4 hours. When the flexible display panel 120 is to be wound up for the third time, the roller controller 160 may rotate the first roller 140 in the second direction corresponding to a shorter one of the first duration (8 hours) or the second duration (4 hours), and the flexible display panel 120 may remain wound in the second direction, for example, for about 2 hours. When the flexible display panel 120 is to be wound up for the fourth time, the roller controller 160 may rotate the first roller 140 in the second direction corresponding to a shorter one of the first duration (8 hours) or the second duration (6 hours), and the flexible display panel 120 may remain wound in the second direction, for example, for about 5 hours. When the flexible display panel 120 is to be wound up for the fifth time, the roller controller 160 may rotate the first roller 140 in the first direction corresponding to a shorter one of the first duration (8 hours) or the second duration (11 hours). In this way, the first duration and the second duration are adjusted so as to be close to each other, so as to prevent a deterioration of the flexible display panel 120.

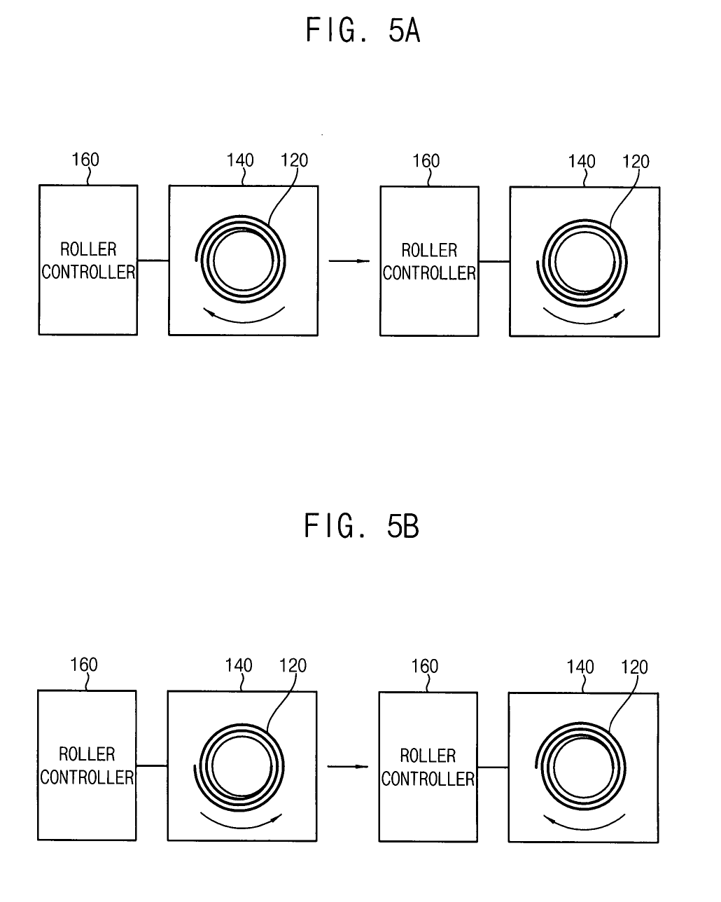

FIGS. 5A and 5B are diagrams illustrating still another example in which a flexible display device of FIG. 1A is controlled such that a flexible display panel is selectively wound in a first direction or a second direction.

Referring to FIGS. 5A and 5B, a roller controller 160 may rotate a first roller 140 in a first direction to re-wind a display panel 120 after it has been wound in a second direction for some period of time. As illustrated in FIG. 5B, the roller controller 160 may rotate the first roller 140 in the second direction to re-wind the display panel 120 after it has been wound in the first direction for some period of time. In one example embodiment, if the flexible display panel 120 is wound in one direction for too long, the roller controller 160 may un-roll the flexible display panel 120 and re-roll it in the other direction. For example, if a duration during which the flexible display panel 120 is wound in a certain direction exceeds 4 hours, the roller controller 160 may control the first roller 140 such that the flexible display panel 120 is un-wound, and then re-wound in the other direction. In another example embodiment, the roller controller 160 may periodically rotate the first roller 140 such that the flexible display panel 120 is un-wound, and then re-wound in the opposite direction. For example, the roller controller 160 may rotate the first roller 140 at 3 AM every day such that the flexible display panel 120 is wound in a direction opposite to the direction in which the flexible display panel 120 was previously wound. In this way, it can be possible to prevent damage to the flexible display panel 120 which may occur when the flexible display panel 120 is wound in one direction for too long of a time.

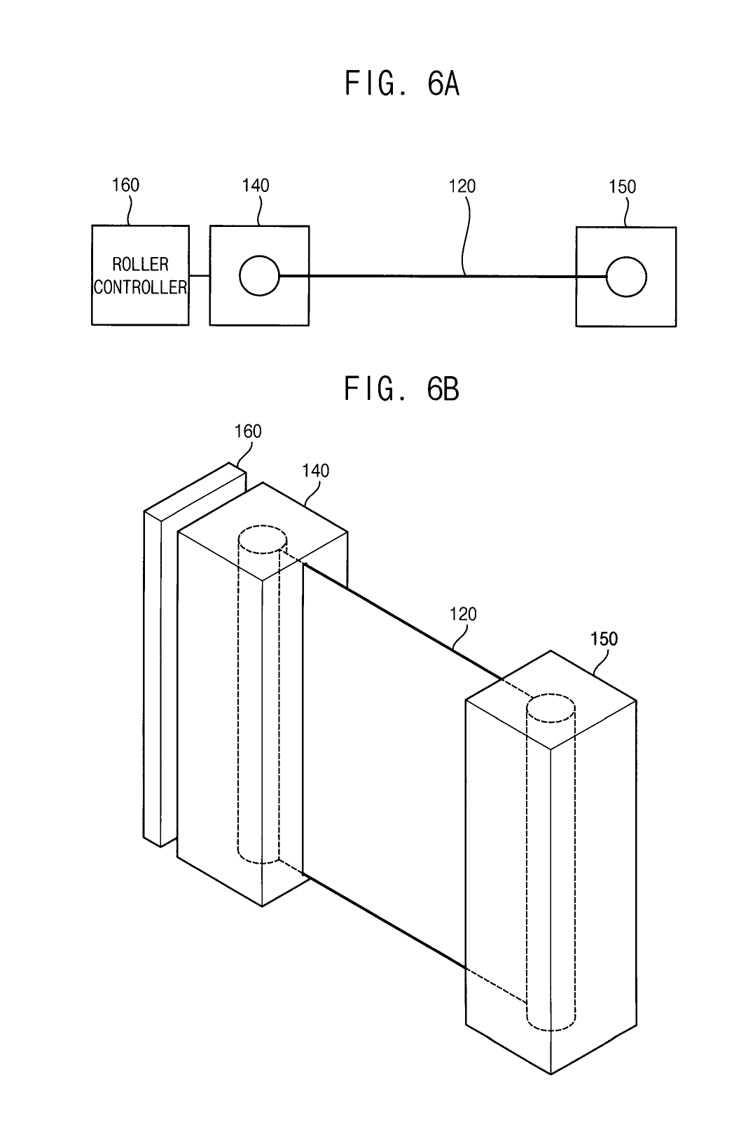

FIG. 6A is a plan view illustrating a flexible display device according to example embodiments, and FIG. 6B is a perspective view illustrating a flexible display device of FIG. 6A.

Referring to FIGS. 6A and 6B, a flexible display device 100 may include a second roller 150 disposed opposite to the first roller 140. The second roller 150 may be selectively rotated in a first direction or in a second direction opposite to the first direction such that a flexible display panel 120 is wound selectively in the first direction or in the second direction. That is, sufficient flexible material is added to each end of the panel 120, so that the panel 120 can be wound. The flexible display device 100 having the second roller 150 may be applicable to various electronic devices such as a television, computer monitor, etc. The flexible display device 100 including a first roller 140 and the second roller 150 may have increased durability.

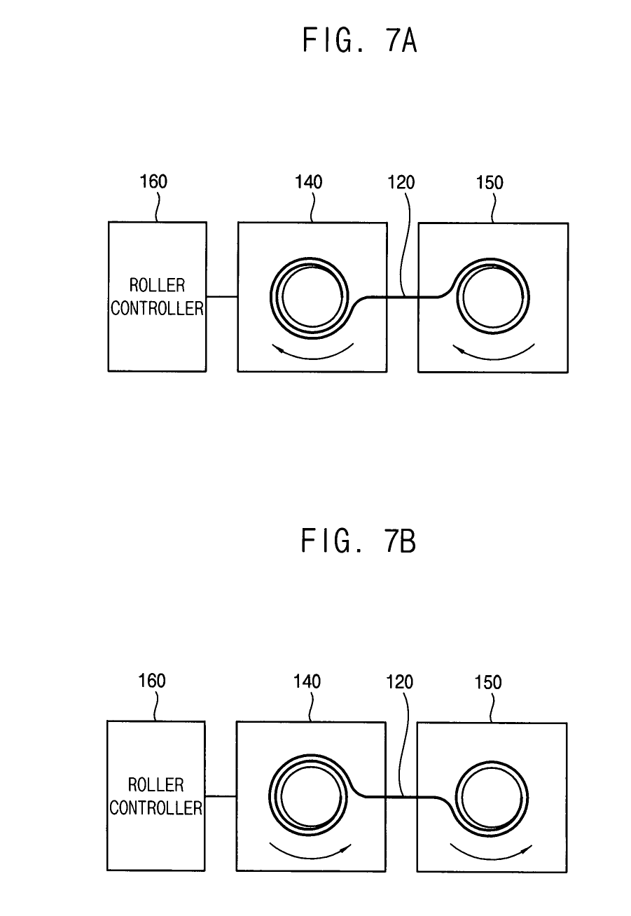

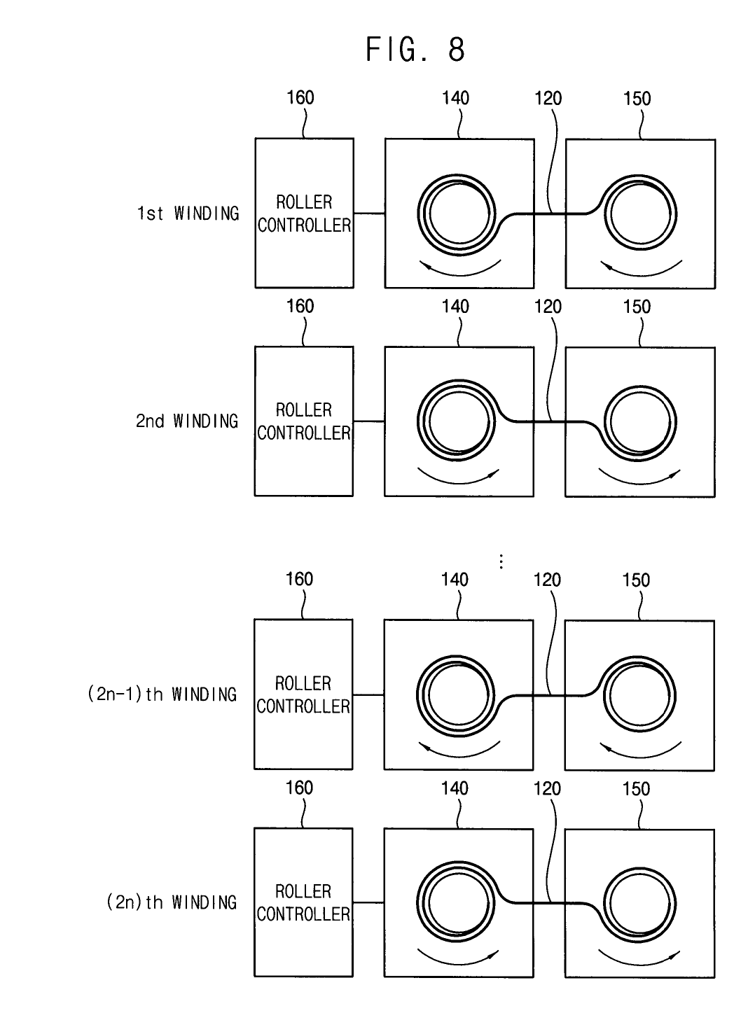

FIGS. 7A and 7B are diagrams illustrating an example in which a flexible display panel included in a flexible display device of FIG. 6A is wound. FIG. 8 is a diagram illustrating an example in which a flexible display device of FIGS. 7A and 7B is controlled.

Referring to FIGS. 7A, 7B and 8, a roller controller 160 may rotate a first roller 140 and a second roller 150 in the same direction. As illustrated in FIG. 7A, the roller controller 160 may rotate the first roller 140 and the second roller 150 in a first direction, so as to wind the flexible display panel 120 around the first roller 140 and the second roller 150. As illustrated in FIG. 7B, the roller controller 160 may rotate the first roller 140 and the second roller 150 in directions opposite to those shown in FIG. 7A. As illustrated in FIG. 8, the roller controller 160 may rotate the first roller 140 and the second roller 150 in a direction opposite to the direction in which a flexible display panel 120 was immediately previously wound. For example, when the flexible display device 100 is not used for the first time, the roller controller 160 may rotate the first roller 140 and the second roller 150 in the first direction so that the panel 120 is wound. Subsequently, the roller controller 160 may rotate the first roller 140 and the second roller 150 so that the panel 120 is partially un-wound for image display. When image display is completed and the flexible display device 100 is out of use, the roller controller 160 may rotate the first roller 140 and the second roller 150 in the second direction so that the display panel 120 is wound.

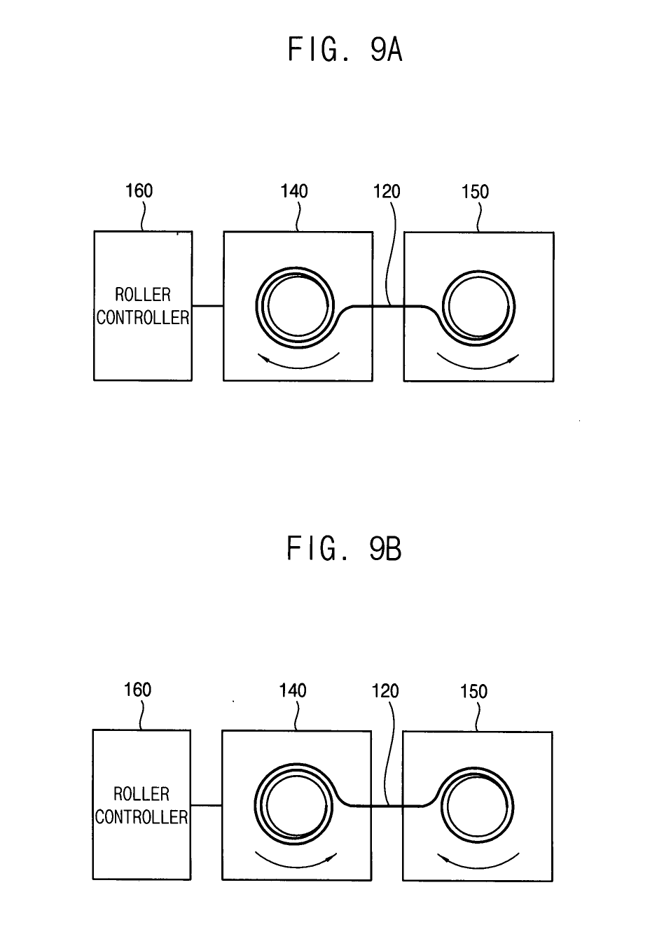

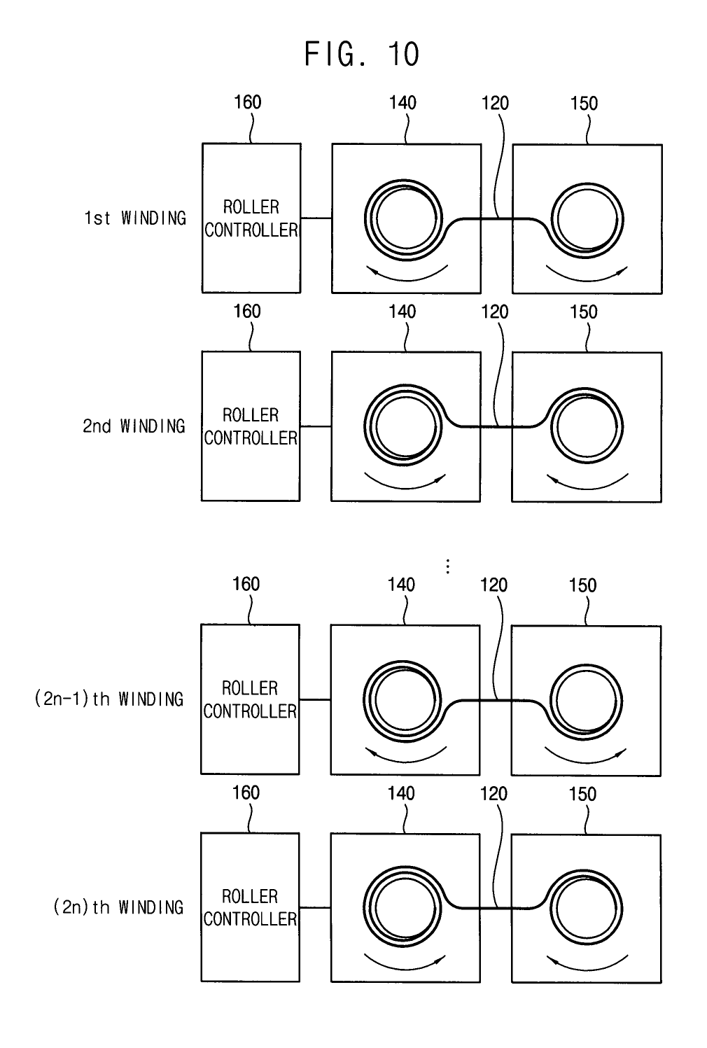

FIGS. 9A and 9B are diagrams illustrating another example in which a flexible display panel included in a flexible display device of FIG. 6A is wound. And FIG. 10 is a diagram illustrating an example in which a flexible display device of FIGS. 9A and 9B is controlled.

Referring to FIGS. 9A, 9B and 10, a roller controller 160 may rotate a first roller 140 and a second roller 150 in opposite directions. As illustrated in FIG. 9A, the roller controller 160 may rotate the first roller 140 in a first direction and may rotate the second roller 150 in a second direction, such that a flexible display panel 120 is wound. As illustrated in FIG. 9B, the roller controller 160 may rotate the first roller 140 in the second direction and may rotate the second roller 150 in the first direction such that the flexible display panel 120 is wound. As illustrated in FIG. 10, the roller controller 160 may rotate the first roller 140 and the second roller 150 in opposite directions. The roller controller 160 may rotate the first roller 140 and the second roller 150 so that the flexible display panel 120 is wound in a direction opposite to the direction in which it was immediately previously wound. For example, when use of the flexible display device 100 is completed, the roller controller 160 may rotate the first roller 140 in the first direction and may rotate the second roller 150 in the second direction so as to wind the display panel 120. Thereafter, the roller controller 160 may rotate the first roller 140 in the second direction and may rotate the second roller 150 in the first direction to unwind the display panel for viewing. When viewing is completed, the roller controller 160 may continue to rotate the first roller 140 in the second direction and may rotate the second roller 150 in the first direction so as to wind the display panel 120.

One of ordinary skill in the art will observe that the flexible display panel 120 can be rolled on the rollers in any direction, and the rollers can be rolled in any direction, so as to allow for any configuration in which the display panel 120 can be rolled on first one and then the other of the rollers. Thus, the display panel 120 can be rolled over or under the rollers as shown, and the rollers can roll the display panel 120 in any manner, such as by turning both rollers in opposite directions, both rollers in the same direction, or any other configuration. Embodiments of the invention contemplate any configuration, positioning, and rolling of the rollers and display panel 120 that allows for the display panel 120 to be rolled in different directions as desired.

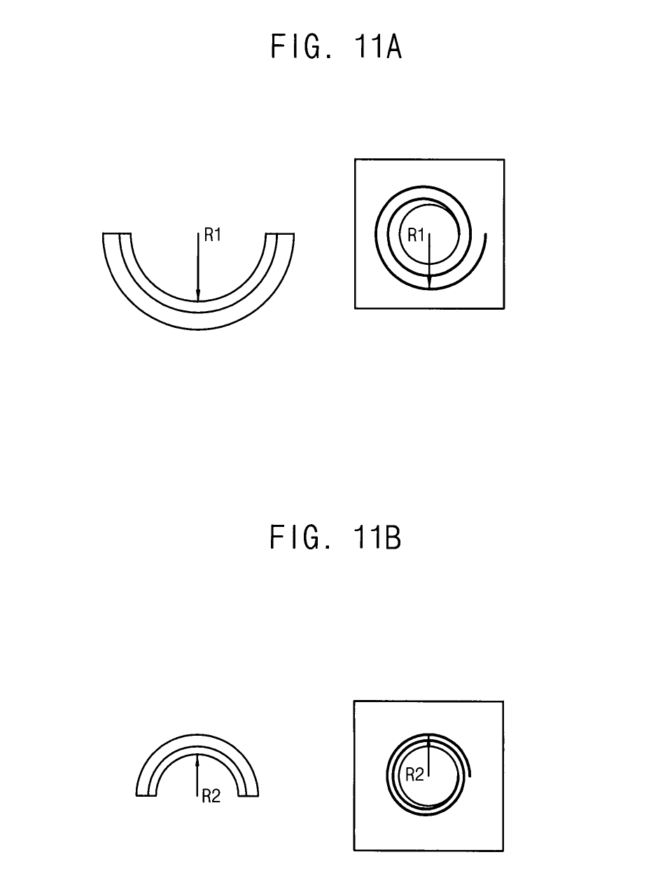

FIGS. 11A and 11B are diagrams illustrating an examples of curvature of a flexible display panel when it is wound.

Referring to FIGS. 11A and 11B, a curvature of a flexible display panel 120 when the flexible display panel 120 is wound in a first direction is different from a curvature of the flexible display panel 120 when the flexible display panel 120 is wound in the second direction. The flexible display panel 120 may have differing upper structures and lower structures on opposing sides of its neutral plane. If the flexible display panel 120 is symmetric with respect to its neutral plane, the curvature of a flexible display panel 120 when the flexible display panel 120 is wound in the first direction and the curvature of the flexible display panel 120 when the flexible display panel 120 is wound in the second direction can be the same. But if the flexible display panel 120 has an upper structure that is different from its lower structure relative to its neutral plane, the curvature of the flexible display panel 120 when the flexible display panel 120 is wound in the first direction may be different from the curvature of the flexible display panel 120 when the flexible display panel 120 is wound in the second direction. Likewise, a curvature of the flexible display panel 120 wound by the first roller 140 may be different from a curvature of the flexible display panel 120 wound by the second roller 150.

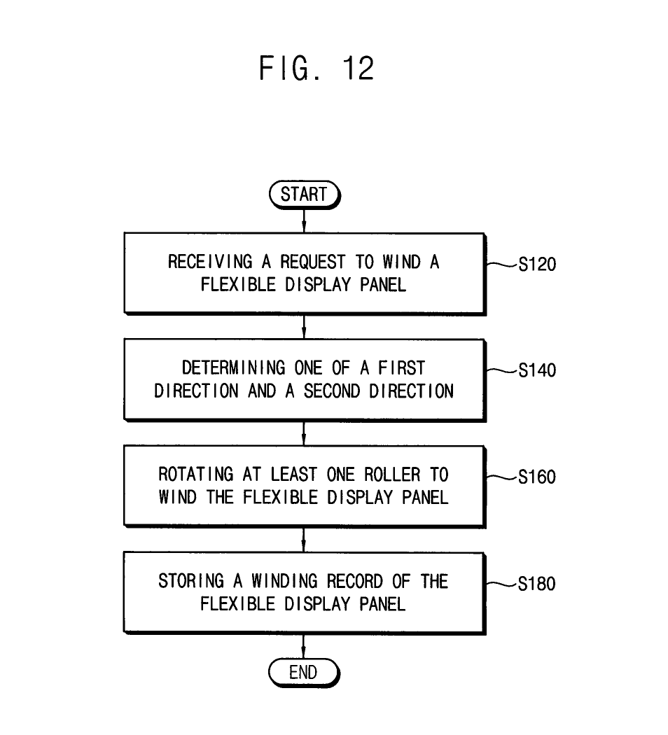

FIG. 12 is a flow chart illustrating a method for controlling a flexible display device according to example embodiments.

Referring to FIG. 12, a roller controller may receive a request to wind a flexible display panel (Step S120), and thus may determine one of a first direction and a second direction opposite to the first direction in which the flexible display panel is to be wound (Step S140). The roller controller may rotate at least one roller to wind the flexible display panel in the determined one of the first direction and the second direction (Step S160), and may also store a winding record of the flexible display panel (Step S180).

In further detail, the roller controller may receive a request to wind a flexible display panel (Step S120). The roller controller may receive such a request from an external source such as a user, or it may be generated automatically by the roller controller itself or any other source upon the meeting of certain criteria, such as when a duration during which the flexible display panel is wound in a fixed direction exceeds a predetermined time. Thus, when certain predetermined conditions are satisfied, the request to wind the flexible display panel may be received. It can be possible to prevent a deterioration of the flexible display panel through winding the flexible display panel in a direction opposite to the direction in which it has been wound for an excessive time. In one example embodiment, the roller controller may receive the request to wind the flexible display panel once the duration during which the flexible display panel has been wound in a certain direction exceeds a predetermined time, and may determine a direction opposite to this direction as being the direction for winding the flexible display panel next. That is, once the display panel has been rolled up in one direction for too long, the roller controller may receive a command to instead wind the display panel up in the opposite direction. In another example embodiment, the request to wind the flexible display panel is periodically received, and the winding direction is determined as the direction opposite to that in which the display panel is currently wound, or was last wound.

In response to the request, the roller controller may determine the direction in which the flexible display panel is to be wound (Step S140). The roller controller may determine one of the first direction and the second direction for equal rolling in both directions. In one example embodiment, the roller controller may determine the direction of rolling as being the direction opposite to the direction in which the flexible display panel was immediately previously wound. In this way, each time the flexible display panel is wound up, it is wound in the opposite direction. In another example embodiment, the roller controller may store a first number of times that the flexible display panel is wound in the first direction and a second number of times that the flexible display panel is wound in the second direction, and may select a direction corresponding to a smaller one of the first number of times or the second number of times. In this way, the flexible display device may be controlled so as to attempt to even out the number of times the display panel is rolled, or wound, in each direction. In another example embodiment, the roller controller may store a first duration during which the flexible display panel is wound in the first direction, and a second duration during which the flexible display panel is wound in the second direction. The roller controller may compare the first duration and the second duration, and may select a direction corresponding to a smaller one of the first duration or the second duration. In this way, the flexible display device may be controlled to attempt to wind the display panel for an equal amount of time in both directions.

The roller controller may store a winding record of the flexible display panel, which is used in controlling the flexible display device (Step 180). In one example embodiment, the roller controller may store a first number of times that the flexible display panel is wound in the first direction and a second number of times that the flexible display panel is wound in the second direction. The first number of times and the second number of times are used in determining a winding direction corresponding to a smaller one of the first number of times or the second number of times. In another example embodiment, the roller controller may store a first duration during which the flexible display panel is wound in the first direction and a second duration during which the flexible display panel is wound in the second direction. The first duration and the second duration are used in determining a winding direction corresponding to a smaller one of the first duration or the second duration.

A conventional flexible display device that is wound in one direction has a problem that a flexible display panel cannot maintain its flatness owing to a deterioration of, or damage to, the flexible display panel when it is kept wound in one direction for too long. Therefore, the conventional flexible display device experiences degraded performance and a shortened life span. On the other hand, a flexible display device according to example embodiments can wind a flexible display panel in either a first direction or a second direction. In this manner, a flexible display device according to example embodiments may maintain its performance for longer, and thus have a greater operational life span.

The present inventive concept may be applied to an electronic device having a flexible display device. For example, the present inventive concept may be applied to a television, a computer monitor, a laptop, a digital camera, a cellular phone, a smart phone, a smart pad, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. The various features of the various embodiments described herein may be mixed and matched in any manner to produce other embodiments consistent with the invention. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A flexible display device comprising:
a flexible display panel;
a first roller configured to wind the flexible display panel thereon; and
a roller controller configured to rotate the first roller in a first direction and in a second direction opposite to the first direction, and to select from between the first direction and the second direction, such that the flexible display panel is wound selectively thereon in either of the first direction and the second direction.

2. The flexible display device of claim 1, wherein the roller controller is configured to rotate the first roller in the first direction when the flexible display panel was previously wound in the second direction, and to rotate the first roller in the second direction when the flexible display panel was previously wound in the first direction.

3. The flexible display device of claim 1, wherein the roller controller is configured to record a first number of times that the flexible display panel is wound in the first direction and a second number of times that the flexible display panel is wound in the second direction, and is configured to select from among the first and second directions so as to rotate the first roller such that the flexible display panel is wound in a direction corresponding to a smaller one of the first number of times or the second number of times.

4. The flexible display device of claim 1, wherein the roller controller is configured to record a first duration during which the flexible display panel is wound in the first direction and a second duration during which the flexible display panel is wound in the second direction, and is configured to select from among the first and second directions so as to rotate the first roller such that the flexible display panel is wound in a direction corresponding to a shorter one of the first duration and the second duration.

5. The flexible display device of claim 1, wherein, if a duration during which the flexible display panel is wound in one of the first and second directions exceeds a predetermined time, the roller controller is configured to rotate the first roller such that the flexible display panel is wound in the other one of the first and second directions.

6. The flexible display device of claim 1, wherein the roller controller is configured to periodically rotate the first roller such that the flexible display panel is successively wound in alternating ones of the first direction and the second direction.

7. The flexible display device of claim 1, wherein a curvature of the flexible display panel when the flexible display panel is wound in the first direction is different from a curvature of the flexible display panel when the flexible display panel is wound in the second direction.

8. The flexible display device of claim 1, further comprising:
a second roller disposed opposite to the first roller relative to the flexible display panel, the second roller configured to wind the flexible display panel.

9. The flexible display device of claim 8, wherein the roller controller is configured to rotate the first roller and the second roller in a same direction.

10. The flexible display device of claim 8, wherein the roller controller is configured to rotate the first roller and the second roller in opposite directions.

11. The flexible display device of claim 8, a curvature of the flexible display panel wound by the first roller is different from a curvature of the flexible display panel wound by the second roller.

12. A method of controlling a flexible display device, the method comprising:
receiving a request to wind a flexible display panel;
determining a direction in which the flexible display panel is to be wound, the direction determined from among a first direction and a second direction opposite to the first direction;
rotating at least one roller to wind the flexible display panel in the determined one of the first direction and the second direction; and
storing a winding record including information corresponding to the determined one of the first direction and the second direction.

13. The method of claim 12, wherein the determining further includes:
selecting a direction opposite to a previous direction in which the flexible display panel was wound.

14. The method of claim 12, wherein storing further includes:
storing a first number of times that the flexible display panel is wound in the first direction and a second number of times that the flexible display panel is wound in the second direction.

15. The method of claim 14, wherein the determining further includes:
comparing the first number of times to the second number of times; and
selecting the direction in which the flexible display panel is to be wound as the direction corresponding to a smaller one of the first number of times and the second number of times.

16. The method of claim 12, wherein the storing further includes:
storing a first duration during which the flexible display panel is wound in the first direction and a second duration during which the flexible display panel is wound in the second direction.

17. The method of claim 16, wherein the determining further includes:
comparing the first duration to the second duration; and
selecting the direction in which the flexible display panel is to be wound as the direction corresponding to a smaller one of the first duration or the second duration.

18. The method of claim 12, wherein the receiving further comprises conditionally receiving the request when a duration during which the flexible display panel is wound in one of the first and second directions exceeds a predetermined time, and
wherein the determining further includes selecting a direction opposite to the one of the first and second directions.

19. The method of claim 12, wherein the receiving further comprises receiving ones of the requests periodically, and
wherein the determining further includes selecting the direction in which the flexible display panel is to be wound as the direction opposite to a direction in which the flexible display panel was immediately previously wound.
